(19) United States
(12) Patent Application Publication
(10) Pub. No.: US 2025/0364274 A1
(43) Pub. Date: Nov. 27, 2025

(54) SEMICONDUCTOR PACKAGE STRUCTURE AND METHOD OF MANUFACTURING THEREOF

(71) Applicant: TAIWAN SEMICONDUCTOR MANUFACTURING COMPANY, LTD., Hsinchu (TW)

(72) Inventors: Yi Chen HO, Taichung (TW); Chien LIN, Hsinchu (TW)

(21) Appl. No.: 19/292,944

(22) Filed: Aug. 7, 2025

Related U.S. Application Data
(62) Division of application No. 17/899,865, filed on Aug. 31, 2022.
(60) Provisional application No. 63/341,375, filed on May 12, 2022.

(51) Int. Cl. H01L 21/56; H01L 23/00; H01L 25/00; H01L 25/065

(52) U.S. Cl. CPC H01L 21/561; H01L 24/27; H01L 25/0655; H01L 25/50; H01L 2224/27466

(57) ABSTRACT

The present disclosure relates to a method for fabricating a system on integrated chip (SoIC) package. Particularly, a glue layer is deposited on sidewalls of semiconductor dies prior to depositing a dielectric filling material between the semiconductor dies. The glue layer may be a nitrogen containing layer, such as silicon nitride, silicon carbon nitride, and silicon oxygen nitride. The dielectric filling material may be a silicon oxide formed from TEOS or mDEOS. The glue layer increases adhesion between the dielectric filling material and semiconductor dies.

### CROSS-REFERENCE TO RELATED APPLICATIONS

This application is a divisional of U.S. patent application Ser. No. 17/899,865 filed Aug. 31, 2022, which claims benefit to U.S. provisional patent application Ser. No. 63/341,375 filed May 12, 2022. Each of the aforementioned applications is incorporated by reference in its entirety.

### BACKGROUND

The semiconductor industry has experienced rapid growth due to continuous improvements in the integration density of a variety of electronic components, e.g., transistors, diodes, resistors, and capacitors. For the most part, this improvement in integration density has come from repeated reductions in minimum feature size, which allows more components to be integrated into a given area as device dies and then packaged into device packages.

The packages of integrated circuits are becoming increasing complex, with more device dies packaged in the same package to achieve more functions. For example, System on Integrate Chip (SoIC) and 3D integrated circuit (3DIC) technologies have been developed to include a plurality of device dies such as processors and memory cubes in the same package. The SoIC can include device dies formed using different technologies and have different functions bonded to the same device die, thus forming a system. In SoIC technology, device dies may be stacked using 3DIC solutions to further reduce footprint of device packages. This may save manufacturing cost and optimize device performance. However, other challenges exist in these processes. For example, instability and stress in materials between semiconductor dies may increase failure rate and cost of manufacturing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing a SoIC (system on integrated circuit) package according to embodiments of the present disclosure.

FIGS. 2, 2A, 3, 3A, 4, 5, 5A, 5B, 6, 6A, 6B, 6C, 7, 8, 9, 9A, 10, 10A, 11, 12, 13, and 14 schematically demonstrate a SoIC package at various stages in manufacturing according to embodiments of the present disclosure.

FIGS. 15-16 are cross sectional views of SoIC device packages formed according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Teachings of the present disclosure are applicable to any package structure including one or more semiconductor dies. Other embodiments contemplate other applications, such as different package types or different configurations that would be readily apparent to a person of ordinary skill in the art upon reading this disclosure. It should be noted that embodiments discussed herein may not necessarily illustrate every component or feature that may be present in a structure. For example, multiples of a component may be omitted from a figure, such as when discussion of one of the components may be sufficient to convey aspects of the embodiment. Further, method embodiments discussed herein may be discussed as being performed in a particular order; however, other method embodiments may be performed in any logical order.

Embodiments of the present disclosure relates to methods for manufacturing packages of semiconductor dies, and device packages manufactured thereof. Methods according to the present disclosure may be used in with 3D integrated circuit (3DIC) and/or System-on-Integrated-Chips (SoIC) solutions to integrate active and passive device dies. Embodiments of the present disclosure meet ever-increasing market demands on higher computing efficiency, wider data bandwidth, higher functionality packaging density, lower communication latency, and lower energy consumption per bit data.

In some embodiments, a glue layer is deposited on semiconductor dies prior to depositing a dielectric filling material between the semiconductor dies. The glue layer may be a nitrogen containing layer, such as silicon nitride, silicon carbon nitride, and silicon oxygen nitride. The dielectric filling material may be a silicon oxide formed from TEOS/tetraethoxysilane or mDEOS/methyldiethoxysilane. The glue layer increases adhesion between the dielectric filling material and the semiconductor dies. Particularly, the glue layer may increase an angle of an interface corner to increase step coverage of subsequent deposition of the dielectric filling material. In some embodiments, a pretreatment may be performed to increase sidewall adhesion ability. The semiconductor dies may be device dies or dummy dies.

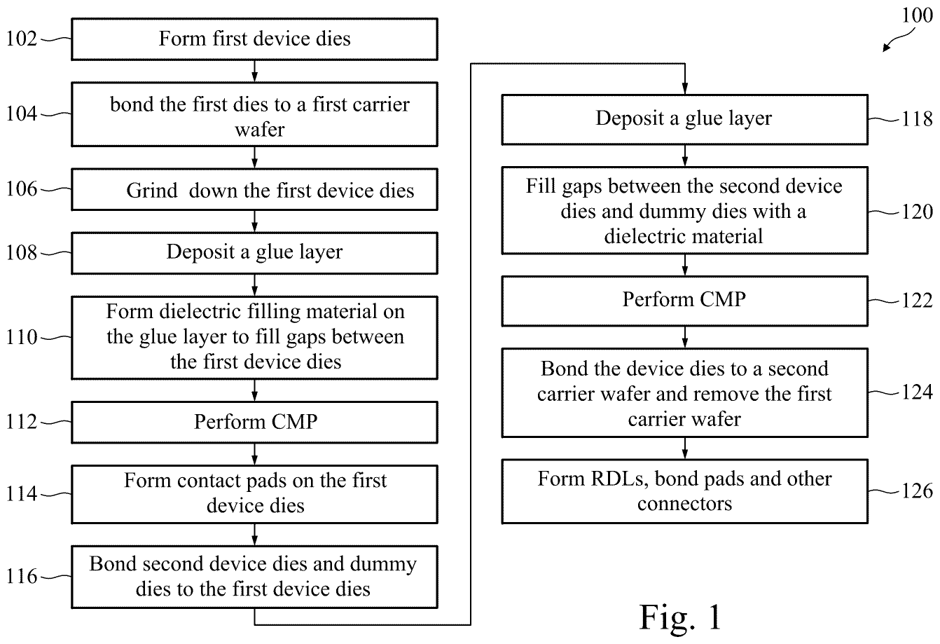

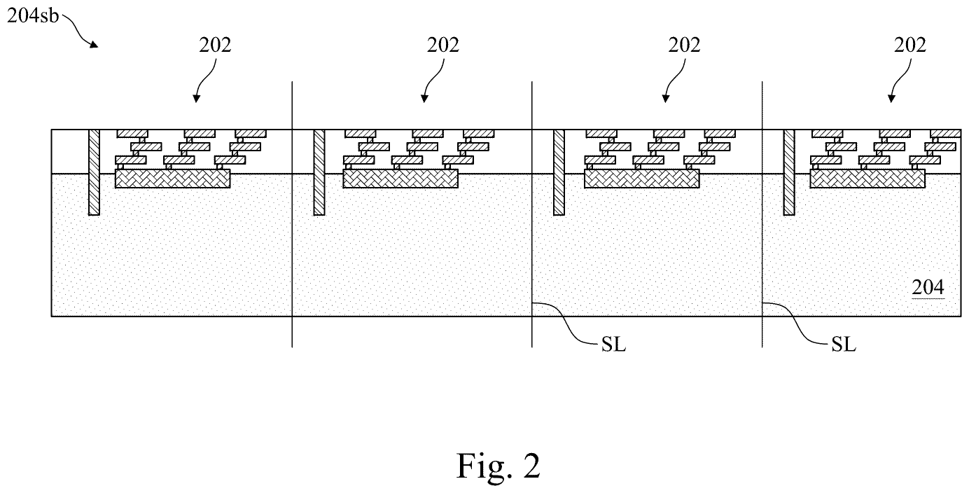

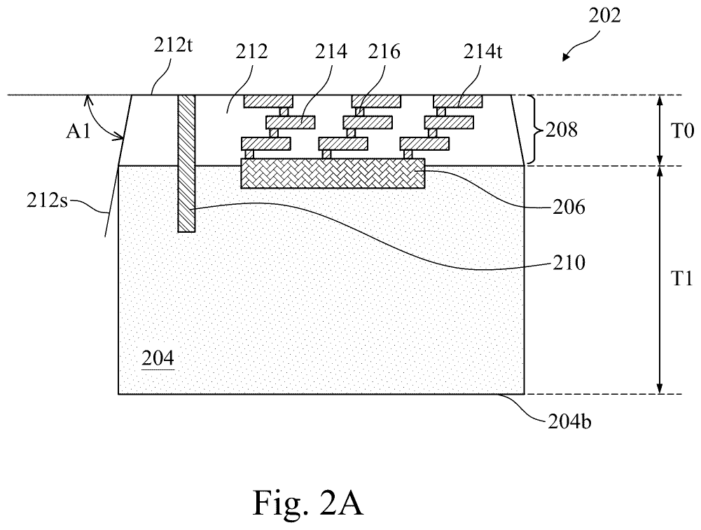

FIG. 1 is a flow chart of a method 100 for manufacturing a SoIC (system on integrated circuit) package according to embodiments of the present disclosure. FIGS. 2, 2A, 3, 3A, 4, 5, 5A, 5B, 6, 6A, 6B, 6C, 7, 8, 9, 9A, 10, 10A, 11, 12, 13, and 14 schematically demonstrate a SoIC package 200 at various stages in manufacturing according to embodiments of the present disclosure. Even though formation of SoIC packages is used as examples to explain the concept of the embodiments of the present disclosure, the embodiments of the present disclosure are readily applicable to other bonding methods and structures in which metal pads and vias are bonded to each other.

In operation 102 of the method 100, device dies 202 are fabricated, as shown in FIGS. 2 and 2A. FIG. 2 is a partial sectional view of a semiconductor substrate 204sb on which a plurality of device dies 202 are fabricated. FIG. 2A is a schematical view of the device die 202 after diced as an individual chip. As shown in FIG. 2, the device dies 202, formed in the semiconductor substrate 204, are defined by intersecting scribe lines SL. After fabrication, the device dies 202 are diced into individual chips along the scribe lines SL. The device die 202 may be used as a package component in a SoIC package according to embodiments of the present disclosure. The device die 202 may be a logic die, which may be a Central Processing Unit (CPU) die, graphics processing unit (GPU) die, a system-on-a-chip (SoC) die, a Micro Control Unit (MCU) die, an input-output (IO) die, a BaseBand (BB) die, an Application processor (AP) die, an analog die, a sensor die, a wireless application die, such as a Bluetooth chip, a radio frequency chip, or a voltage regulator die, or the like. The device die 202 may also be a memory die such as a Dynamic Random Access Memory (DRAM) die or a Static Random Access Memory (SRAM) die.

The device die 202 may include a device layer 206 formed in and on the semiconductor substrate 204. The device layer 206 may include active components, such as transistors and/or diodes, and passive components such as capacitors, inductors, resistors, or the like. The device die 202 may further includes an interconnect structure 208 formed over the device layer 206 to provide electrical connections to the device layer 206. In some embodiments, the device die 202 may include through semiconductor vias 210 configured to provide electrical connections to a device die to be vertically bond to the device die 202.

In some embodiments, the semiconductor substrate 204 may be made of elemental semiconductor materials such as crystalline silicon, diamond or germanium; compound semiconductor materials such as silicon carbide, gallium arsenic, indium arsenide or indium phosphide, or alloy semiconductor materials such as silicon germanium, silicon germanium carbide, gallium arsenic phosphide or gallium indium phosphide. In some embodiments, the semiconductor substrate 204 may be a bulk semiconductor material. For example, the semiconductor substrate 204 may be a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. However, the disclosure is not limited thereto. In some alternative embodiments, the semiconductor substrate 204 may include active components (e.g., transistors and/or memories such as NMOS and/or PMOS devices, or the like) and optionally passive components (e.g., resistors, capacitors, inductors or the like) formed therein. The active components and passive components of the device layer 206 are formed in the semiconductor substrate 204 through front end of line (FEOL) fabrication processes.

In some embodiments, the interconnect structure 208 is disposed on the semiconductor substrate 204 and the device layer 206. In some embodiments, the interconnect structure 208 is electrically connected with the active components and/or the passive components formed in the device layer 206. The interconnect structure 208 is formed through back end of line (BEOL) fabrication processes of the semiconductor substrate 204.

The interconnect structure 208 may include dielectric layers 212, conductive lines 214 and conductive vias 216 embedded in the dielectric layers 212. The dielectric layers 212 are alternatively referred to as Inter-Metal Dielectric (IMD) layers 212 hereinafter. In accordance with some embodiments of the present disclosure, at least the lower ones of the dielectric layers 212 are formed of a low-k dielectric material having a dielectric constant (k-value) lower than about 3.0 or about 2.5. The dielectric layers 212 may be a carbon-containing low-k dielectric material, Hydrogen SilsesQuioxane (HSQ), MethylSilsesQuioxane (MSQ), or the like. In accordance with alternative embodiments of the present disclosure, some or all of dielectric layers 212 are formed of non-low-k dielectric materials such as silicon oxide, silicon carbide (SiC), silicon carbo-nitride (SiCN), silicon oxy-carbo-nitride (SiOCN), or the like. In accordance with some embodiments of the present disclosure, the formation of dielectric layers 212 includes depositing a porogen-containing dielectric material, and then performing a curing process to drive out the porogen, and hence the remaining dielectric layers 212 becomes porous. Etch stop layers (not shown), which may be formed of silicon carbide, silicon nitride, or the like, are formed between the dielectric layers 212, and are not shown for simplicity. The conductive lines 214 at the top most level are sometimes referred to as a top metal layer 214t.

The conductive lines 214 and conductive vias 216 are formed in dielectric layers 212. The conductive lines 214 at a same level are sometimes collectively referred to as a metal layer. The interconnect structure 208 includes a plurality of metal layers that are interconnected through the conductive vias 216. The conductive lines 214 and conductive vias 216 may be formed of copper or copper alloys, and they can also be formed of other metals. The formation process may include single damascene and dual damascene processes.

In some embodiments, the through semiconductor vias 210 are formed in the semiconductor substrate 204 and the interconnect structure 208. In some embodiments, the through semiconductor vias 210 are electrically connected with the conductive lines 214 in the interconnect structure 208. The through semiconductor vias 210 are embedded in the semiconductor substrate 204 and the interconnect structure 208. As shown in FIG. 2A, the interconnect structure 208 may have a thickness and the semiconductor substrate 204 may have an original thickness T1. In some embodiments, the thickness T0 may be in a range between about 13 μm and about 17 μm. In some embodiments, the thickness T1 may be in a range between about 90 μm and about 110 μm. In some embodiments, the through semiconductor vias 210 may be formed within the semiconductor substrate 204 and are not revealed from a bottom surface 204b of the semiconductor substrate 204 during fabrication.

As shown in FIG. 2A, the dielectric layers 212 in the device die 202 may have some shrinkage relative to the semiconductor substrate 204. As a result of the shrinkage, a sidewall 212s of the device die 202 is sloped. An angle A1 between the sidewall 212s and a top surface 212t of the dielectric layers 212 may be deviated from 90 degrees due to the shrinkage. In some embodiments, the angle A1 may be in a range between about 85 degrees and about 90 degrees.

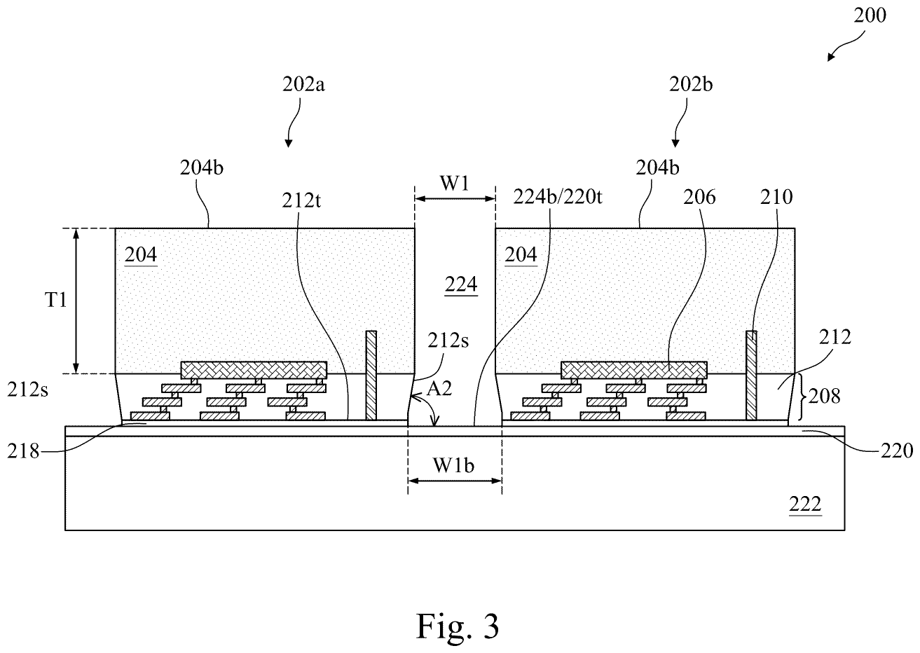

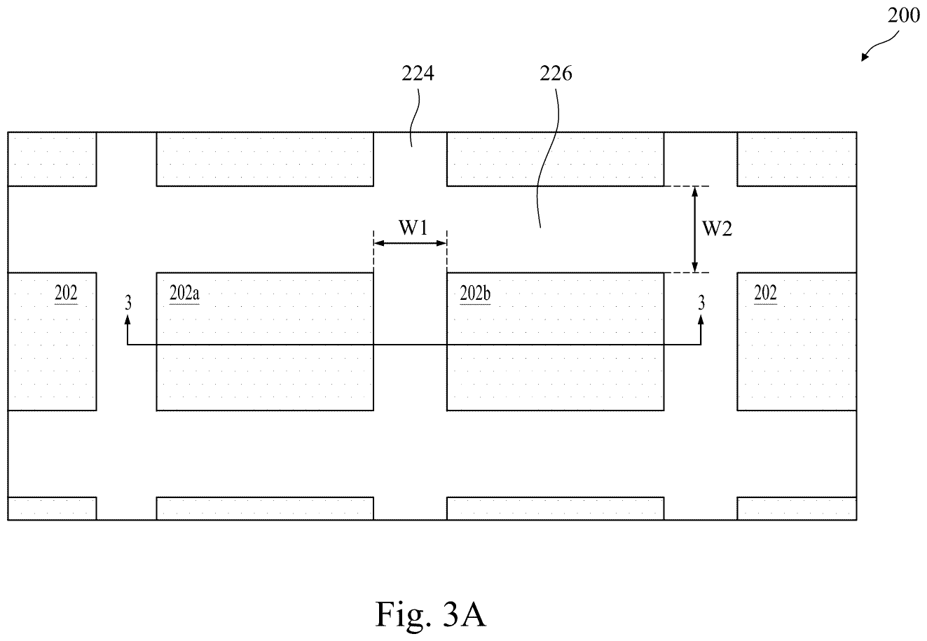

At operation 104, the device dies 202 are bonded to a carrier wafer 222 as shown in FIGS. 3 and 3A. FIG. 3A is a schematic partial top view of the carrier wafer 222 showing the plurality of device dies 202 arranged thereon. FIG. 3 is a schematic sectional view of the carrier wafer 222 and the device dies 202 along the line 3-3 on FIG. 3A. As shown in FIG. 3A, the device dies 202 are arranged on the carrier wafer 222 so that a plurality of SoIC dies are to be formed thereon. The device dies 202 may be the identical or different depending on particular design of the SoIC dies to be formed. In some embodiments, the device dies 202 may be arranged side by side with gaps 224, 226 formed therebetween. In some embodiments, the gaps 224 may be internal gaps between device dies within one SoIC die, and the gaps 226 are external gaps as borders between neighboring SoIC dies. After packaging, the SoIC dies would be separated by cutting along the gaps 226. The gaps 226 may be wider than the gaps 224. The gaps 224 has a first width W1. The gaps 226 has a second width W2. In some embodiments, the first width W1 is in a range between about 75 μm and about 95 μm. The second width W2 is in a range between about 190 μm and 210 μm.

The carrier wafer 222 may be a glass carrier substrate, a ceramic carrier substrate, or the like. In some embodiments, a release layer 220 may be formed on the carrier wafer 222. The release layer 220 may be formed of a polymer-based material, which may be removed along with the carrier wafer 222 from overlying structures to be formed in subsequent steps. In some embodiments, the release layer 220 is an epoxy-based thermal-release material, which loses its adhesive property when heated, such as a light-to-heat-conversion (LTHC) release coating. In other embodiments, the release layer 220 may be an ultra-violet (UV) glue, which loses its adhesive property when exposed to UV light. The release layer 220 may be dispensed as a liquid and cured, may be a laminate film laminated onto the carrier wafer 222, or may be the like. A top surface of the release layer 220 may be leveled and may have a high degree of planarity.

In some embodiments, an adhesive layer 218 is formed over the top surface 212t of the device dies 202. The device dies 202 is then attached to the release layer 220 of the carrier wafer 222 by the adhesive layer 218. The adhesive layer 218 may be any suitable adhesive, epoxy, die attach film (DAF), or the like. The device dies 202 may be adhered to the release layer 220 using a pick-and-place tool.

In the example, at least two semiconductor dies 202a, 202b are included in the SoIC package 200 to be formed. Depending on circuit design, the device dies 202a, 202b may be identical or different. The gap 224 is formed between the device dies 202a, 202b. Because the ILD layers 212 may have suffered a shrinkage, after the device dies 202 are attached to the carrier wafer 222 with the ILD layers 212 facing down, the gaps 224, 226 are trenches with a wider bottom and narrower entrance. As shown in FIG. 3, the gap 224 has a width W1 at an upper portion and a bottom width W1b near a bottom portion. In some embodiments, the bottom width W1b may be greater than the width W1 in a range between about 0.5 μm and about 5 μm. At the bottom portion, an angle A2 is formed between the sidewall 212s and a bottom surface 224b or a top surface 220t of the carrier wafer 222. The angle A1 is less than 90 degrees due to the shrinkage of the ILD layers 212. In some embodiments, the angle A2 may be in a range between about 85 degrees and about 90 degrees. The wider bottom portion and the angle A2 make the gaps 224 and 224 difficult to fill at the bottom portion, which may lead to poor adhesion on between sidewalls of the device dies 202 and filling materials in the gaps 224, 226.

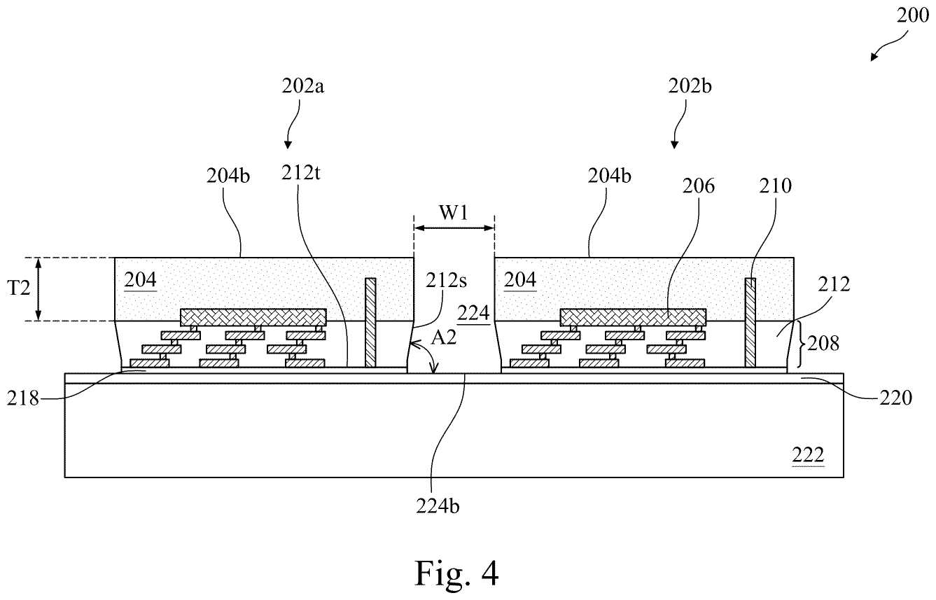

At operation 106, an optional backside grinding may be performed to thin the device dies 202, as shown in FIG. 4. FIG. 4 is a schematic sectional view of the SoIC package 200 after the grinding operation. After the grinding operation, the semiconductor substrate 204 may have a reduced thickness T2. In some embodiments, the thickness T2 may be in a range between about 10 μm and about 15 μm. By grinding down the semiconductor substrate 204 of the device dies 202, aspect ratios of the gaps 224, 226 are reduced to facilitate subsequent back gap filling. In some embodiments, the backside grinding may terminate prior to the through semiconductor vias 210 are revealed leaving a layer of the semiconductor substrate 204 to protect the through semiconductor vias 210.

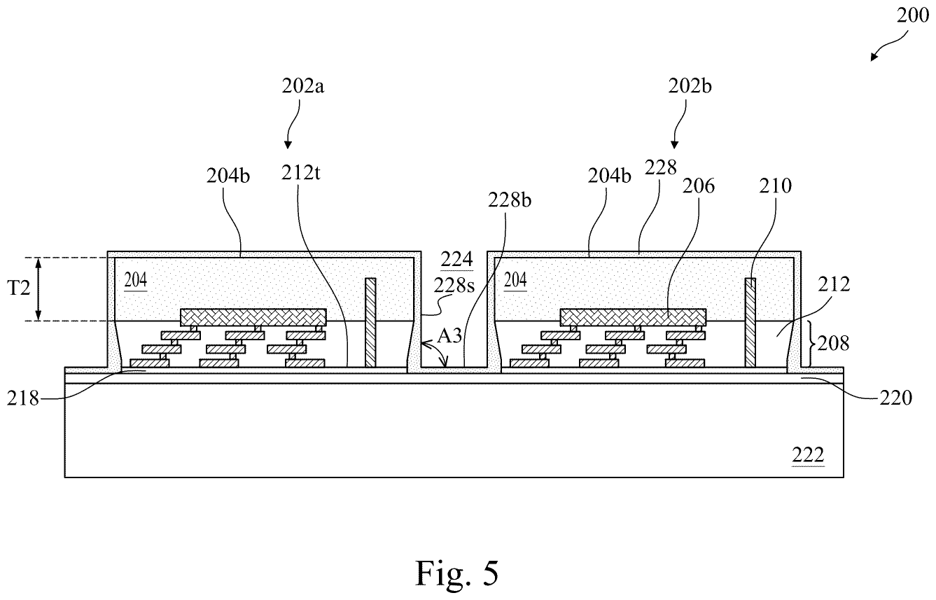

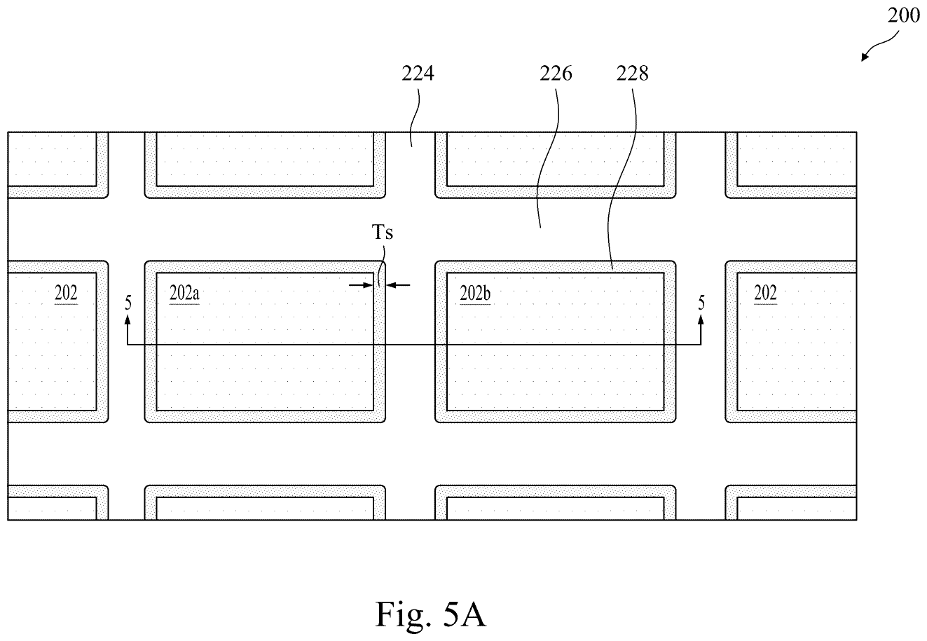

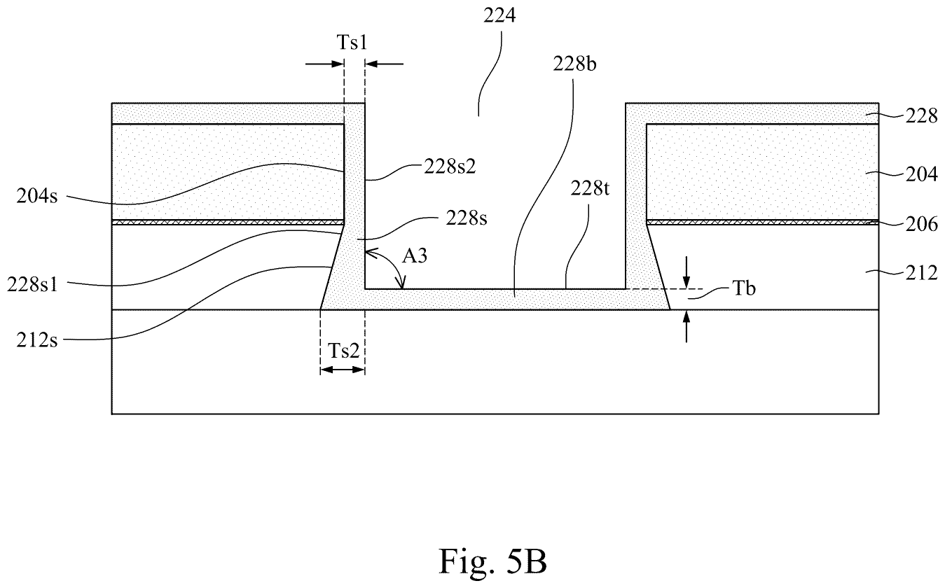

At operation 108, a glue layer 228 is deposited on the exposed surfaces as shown in FIGS. 5, 5A, and 5B. FIG. 5A is a schematic partial top view of the SoIC package 200 with the plurality of device dies 202 arranged on the carrier wafer 222. FIG. 5 is a schematic sectional view of the carrier wafer 222 and the device dies 202 along the line 5-5 on FIG. 5A. FIG. 5B is a partial enlarged view of the SoIC package 200 showing details of the glue layer 228 in the gap 224.

The glue layer 228 may be formed from a nitrogen containing material configured to improve adhesion between the device dies 202 and the gap filling materials. In some embodiments, the glue layer 228 may be silicon nitride (SiN), silicon carbide nitride (SiCN), silicon oxy-carbide nitride (SiOCN), or the like. The glue layer 228 may be formed by chemical vapor deposition (CVD), physical vapor deposition (PVD), atomic layer deposition (ALD), furnace deposition, or other suitable methods.

In some embodiments, the glue layer 228 may be SiN or SiNC formed from precursors comprising NH₃, SiH₂Cl₂, and CH₃. In one embodiment, the glue layer 228 is formed by CVD using precursors containing NH₃, SiH₂Cl₂, and CH₃, at a temperature in a range between about 270° C. and about 280° C., at a pressure between about 3 torr and about 5 torr. In another embodiments, the glue layer 228 is formed by furnace deposition using precursors containing NH₃, SiH₂Cl₂, and CH₃, at a temperature in a range between about 270° C. and about 280° C., at a pressure between about 2 torr and about 5 torr.

In the gap 224, the glue layer 228 includes a sidewall portion 228s and a bottom portion 228b. The sidewall portion 228s may have a thickness Ts and the bottom portion 228b may have a thickness Tb. In some embodiments, the thickness Ts may be in a range between about 500 angstroms and about 2000 angstroms. A thickness less than 500 angstroms may not provide meaningful improvement in adhesion between the device dies 202 and the subsequently formed filling material layer. A thickness greater than 2000 angstroms may increase aspect ratio of the gap 224 without additional improvement of adhesion. In some embodiments, the thickness Tb may be in a range between about 750 angstroms and about 2000 angstroms.

In some embodiments, the glue layer 228 has a non-uniform sidewall thickness, thus, altering the angle A1 at a bottom corner of the gap 224, as shown in FIG. 5B. The sidewall portion 228s has a first side 228s1 in contact with the device die 202 and a second side 228s2 exposed to the gap 224. An upper portion of the first side 228s1 is in contact with a sidewall 204s of the semiconductor substrate 204 and a lower portion of the first side 228s1 is in contact with the sidewall 212s of the dielectric layers 212. As shown in FIG. 5B, the upper portion of the sidewall portion 228s has a thickness Ts1 and the lower portion of the sidewall portion 228s has a thickness Ts2. In some embodiments, the glue layer 228 is deposited so that the thickness Ts2 is greater than the thickness Ts1. In some embodiments, the thickness Ts1 may be in a range about 500 angstroms and about 1500 angstroms, and the thickness Ts2 may be in a range about 1000 angstroms and about 2000 angstroms. The thicker lower portion reduces a width of the gap 224 near the bottom, altering the shape of the gap 224 and facilitating gap filling.

After deposition of the glue layer 228, the gap 224 has a corner angle A3 defined by the glue layer 228. Particularly, the corner angle A3 is defined by the second side 228s2 of the sidewall portion 228s and a top surface 228t of the bottom portion 228b. In some embodiments, the corner angle A3 is in a range between about 85 degrees and about 120 degrees. Particularly, the corner angle A3 may be in a range between about 90 degrees and about 120 degrees.

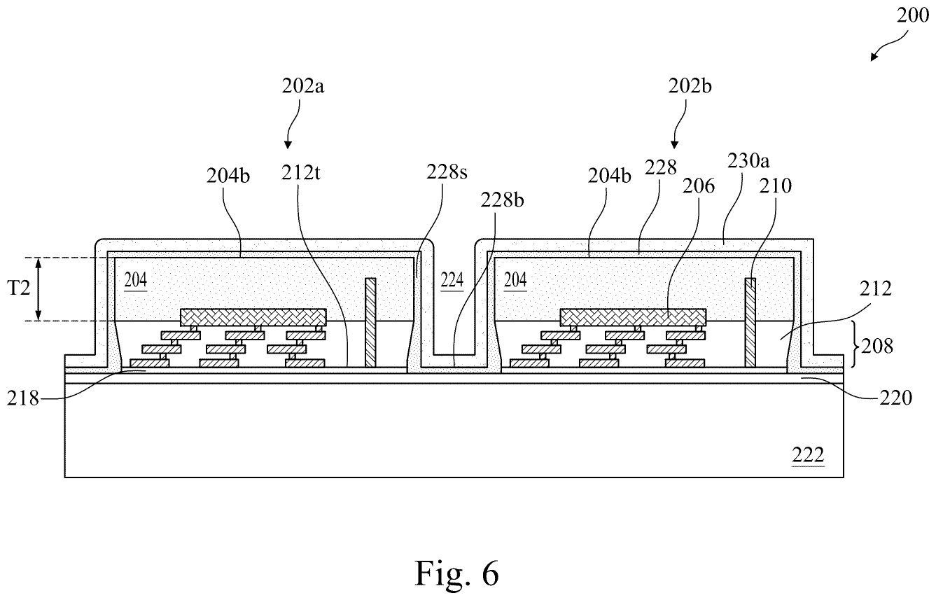

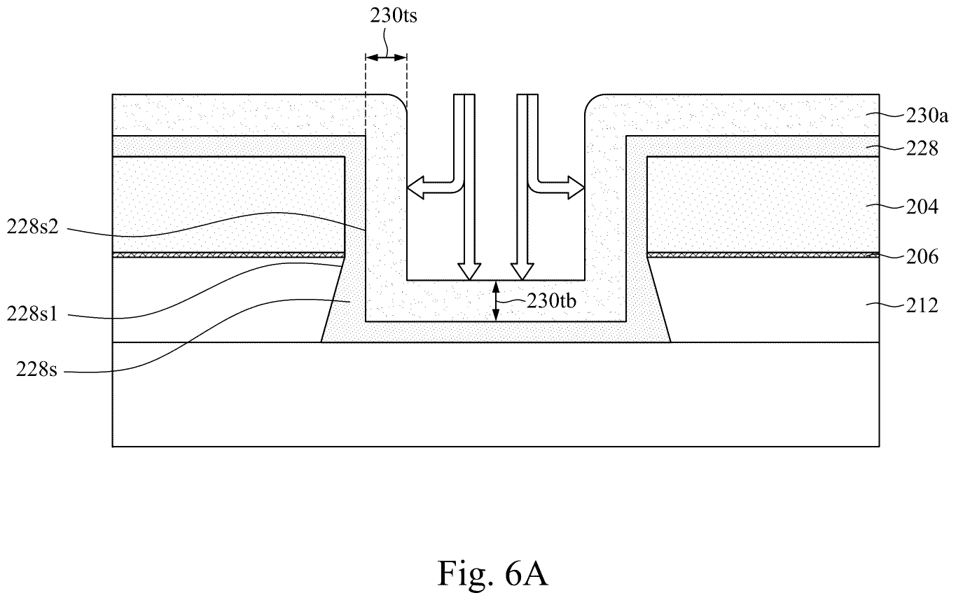

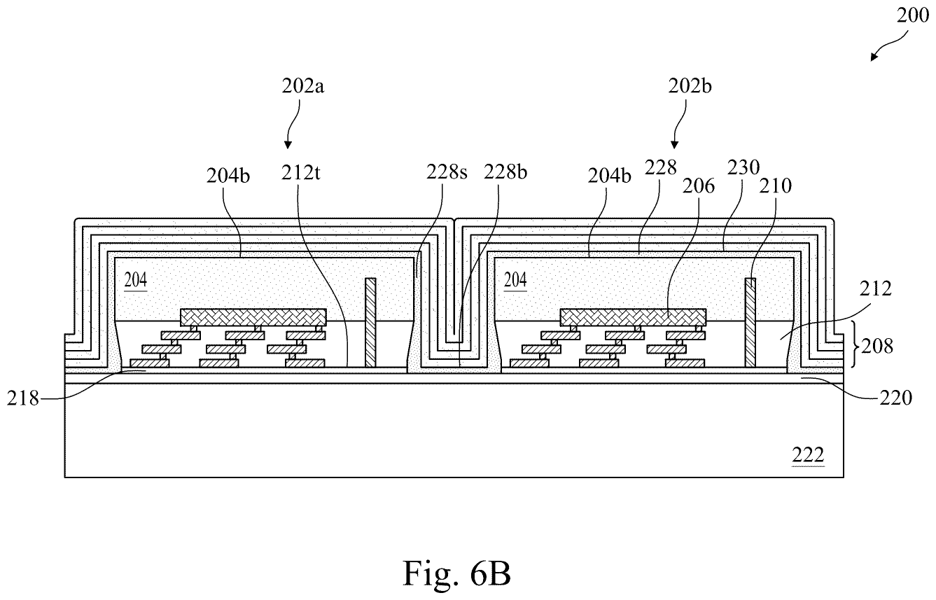

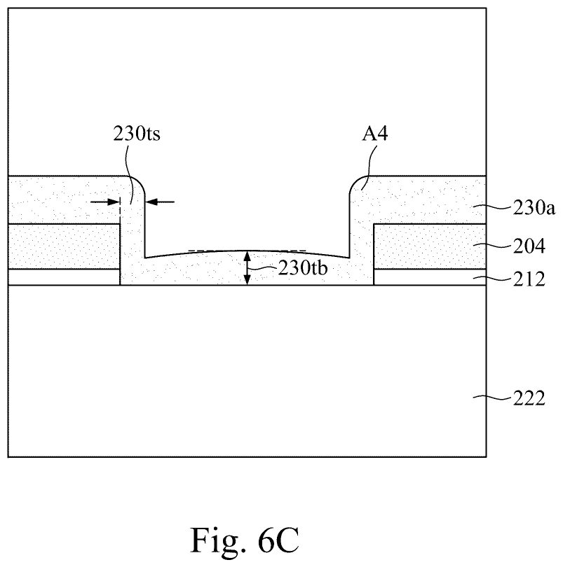

At operation 110, a dielectric filling material 230 is formed over the glue layer 228 filling the gaps 224, 226, as shown in FIGS. 6, 6A and 6B. In some embodiments, the dielectric filling material 230 is deposited by multiple rounds to achieve good step coverage. FIG. 6 is a schematic sectional view of the SoIC package 200 after one round of a first round of dielectric filling material 230a is deposited on the glue layer 228. FIG. 6A is a partial enlarged view of the SoIC package 200 showing the dielectric filling material 230a in the gap 224. FIG. 6B is a schematic sectional view of the SoIC package 200 after the gaps 224 are fully filled with the dielectric filling material 230. FIG. 6C is a TEM image of an example SoIC package after one round of dielectric filling material is deposited on the glue layer.

The dielectric filling material 230 may include a porous low-k material, for example silicon oxide, silicon carbide, silicon oxynitride, silicon oxy-carbo-nitride, PSG, BSG, BPSG, or the like may also be used. The dielectric filling material 230 may be formed using CVD, High-Density Plasma Chemical Vapor Deposition (HDPCVD), Flowable CVD, spin-on coating, or the like.

In some embodiments, the dielectric filling material 230 is a silicon oxide formed using a precursor containing TEOS (tetraethoxysilane, Si(OC₂H₅)₄) by a PECVD process. Traditionally, silicon oxide from TEOS precursor is formed at a temperature greater than about 400° C. According to embodiments of the present disclosure, the dielectric filling material 230 is formed by PECVD process using a TEOS containing precursor at a temperature under about 280° C. to prevent any device decay in the device dies 202 during processing. In some embodiments, the dielectric filling material 230 is formed using a precursor gas containing TEOS and oxygen (O₂). The PECVD process may be performed at a pressure level from about 2 torr to about 10 torr. For example, the dielectric filling material 230 comprises silicon oxide formed by the following reactions:

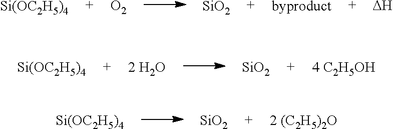

In another embodiment, the dielectric filling material 230 is a silicon oxide formed using a precursor gas containing mDEOS (diethoxymethylsilane, C₅H₁₄O₂Si) and O₂ by a CVD process and a UV (ultra violet) curing. In some embodiments, porogenic compounds may be added to the precursor gas to form a porous film. The porogenic compound may be a carbon-rich precursor including alpha-terpinene (ATRP), ethylene (C₂H₄) or a chemical corresponding to the general formula (CH₃)₂CHC₆H₆—CₙH₂ₙ₊₁ (n is a positive integer). During deposition, plasma of mDEOS, O₂, and the porogen precursor react to form a film containing silicon, oxygen, and CxHy. In the subsequent UV curing process, the CxHy based compound are decomposed forming substantially uniformal porous that is greater than 10 angstrams in diameter. The deposition is performed at a temperature under about 280° C. and a pressure level from about 3 torr to about 5 torr. In some embodiments, the dielectric filling material 230 formed from mDEOS and a porogen may have a dielectric constant of about 2.6 and hardness in a range between about 1.8 Gpa and about 2.0 Gpa.

In some embodiments, a pre-treatment is performed to increase sidewall adhesive ability of the silicon oxide from TEOS or mDEOS. In some embodiments, the pretreatment is performed by providing a O₂ gas flow at a pressure range between about 6 torr to about 8 torr. The pre-treatment increases oxygen atoms on the glue layer 228, such as on the side 228s2 of the sidewall portion 228s, to improve adhesion between the glue layer 228 and the dielectric filling layer 230 on the sidewall portion 228s.

In some embodiments, the dielectric filling material 230 is deposited by multiple rounds of PECVD deposition. FIGS. 6 and 6A are schematic sectional views of the gap 224 after one round of dielectric material 230a is deposited. In some embodiments, a layer with a thickness in a range between about 10 μm and about 25 μm deposited in each round. In some embodiments, a pressure is broken between rounds. For example, the SoIC package 200 is exposed to atmospheric environment between rounds. Exposing the dielectric filling material 230 between deposition improves step coverage of the dielectric filling material 230. In some embodiments, 3 to 7 rounds of deposition may be performed to fully fill the gaps 224 and 226. Alternatively, an oxygen pre-treatment may be performed between the rounds of deposition instead of breaking vacuum. FIG. 6B schematically demonstrates the SoIC package 200 after the gaps 224, 226 are fully filled by the dielectric filling material 230 after multiple rounds of deposition.

As shown in FIG. 6A, after the first round of deposition, the dielectric filling material 230a has a sidewall thickness 230ts along the sidewalls and a horizontal thickness 230tb on horizontal surfaces. According to embodiments of the present disclosure, a step coverage, which is denoted by a ratio of the sidewall thickness 230ts over the horizontal thickness 230tb, is in a range between about 85% and about 95%. In some embodiments, the step coverage is greater than 90%. If the glue layer 228 is omitted, with other conditions remain the same, the step coverage ratio is between about 80% and about 82%. Therefore, using the glue layer 228 provides better gap filling.

FIG. 6C is a TEM image of an example SoIC package after a first round of dielectric filling material is deposited on the glue layer, which is too thin to be visible in the TEM image. As shown in FIG. 6C, the dielectric filling material has a sidewall thickness in a range between 12 μm and 22 μm, and a horizontal thickness in a range between 22 μm and 25 μm. The dielectric filling material forms an angle A4 at a range between 85 degrees and 125 degrees.

In some embodiments, an annealing process is performed to improve strength of the dielectric filling material 230. In some embodiments, an annealing process may be performed at a temperature between about 270° C. and about 280° C. The dielectric filling material 230 on the sidewalls, formed from TEOS according to embodiments of the present disclosure, has a hardness in a range between about 5.93 GP and about 6.78 Gpa and Young's Modulus in a range between about 45.70 Gpa and about 54.36 Gpa. The dielectric filling material 230 on the horizontal surfaces, formed from TEOS according to embodiments of the present disclosure, has a hardness in a range between about 7.89 GP and about 8.72 Gpa and Young's Modulus in a range between about 58.94 Gpa and about 61.25 Gpa.

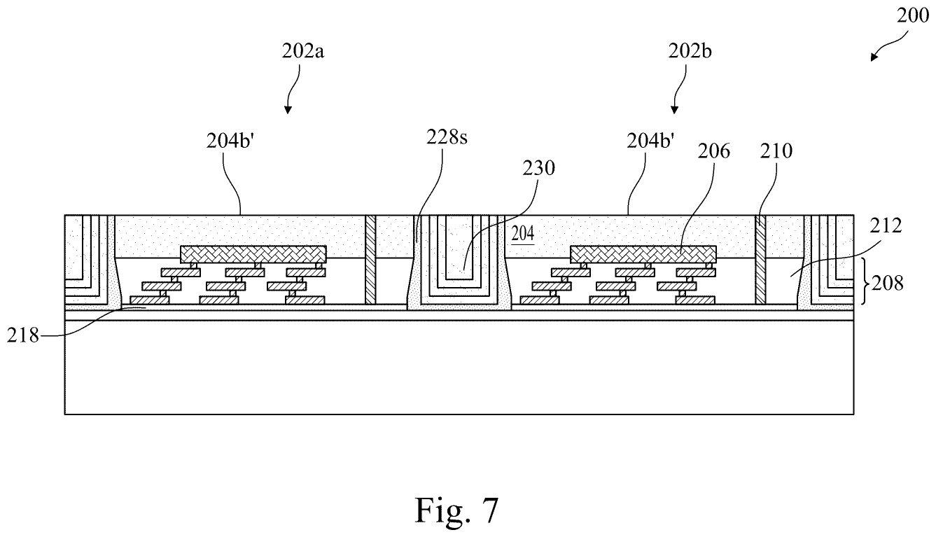

At operation 112, a planarization process is performed to remove the excessive dielectric filling material 230 and expose the device dies 202a, 202b, as shown in FIG. 7. FIG. 7 is a schematic sectional view of the SoIC package 200 after the planarization process. In some embodiments, the planarization process may be performed by a CMP process. In some embodiments, the planarization process may further grind down the semiconductor substrate 204 and terminate when the through semiconductor vias 210 are exposed. The semiconductor substrate 204 is grinded down to a thickness T3 with a bottom surface 204b′. After the planarization process, a top surface 230t of the dielectric filling material 230 is substantially co-planar with the bottom surface 204b′.

During planarization process, after the device dies 202 are exposed, the device dies 202 is subject to external shearing forces. The device dies 202 may be pulled off by the CMP pad or cracked (arcing) during planarization if not securely attached. The glue layer 228 according to the present disclosure improves adhesion between the device dies 202 and the dielectric filling material 230, thus, preventing loss of device dies 202 during the planarization process.

When a thickness of about 750 angstroms of SiN is deposited as the glue layer 228 and the SoIC package 200 is annealed at a temperature between about 240° C. and 250° C., the crack rate of the device dies 202 is less than 27%. When a thickness of about 2000 angstroms of SiN is deposited as the glue layer 228 and the SoIC package 200 is annealed at a temperature between about 240° C. and 250° C., the crack rate of the device dies 202 is between 1.5% and 4.5%. When a thickness of about 750 angstroms of SiN is deposited as the glue layer 228 and the SoIC package 200 is annealed at a temperature between about 270° C. and 280° C., the crack rate of the device dies 202 is less than 1%. When a thickness of about 2000 angstroms of SiN is deposited as the glue layer 228 and the SoIC package 200 is annealed at a temperature between about 270° C. and 280° C., the crack rate of the device dies 202 is about 0%. Therefore, the crack rate may be reduced by increasing the thickness of the glue layer 228 and/or by increasing the annealing temperature to almost 280° C.

In some embodiments, the SoIC package 200 includes a second tier of device dies stacked over the device dies 202, operations 114-122 may be performed to stack the second tier of device dies. In some embodiments, the SoIC package 200 may include one tier of device dies 202, operations 114-122 may be omitted, and operation 124 is performed after operation 112 to complete fabrication of the SoIC package 200.

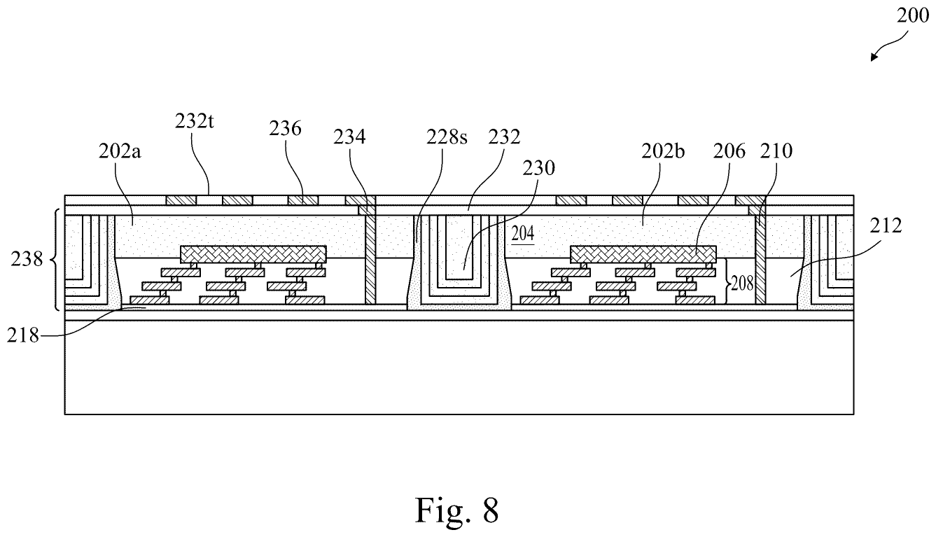

In operation 114, conductive pads 236 are formed over the device dies 202 as shown in FIG. 8. In some embodiments, bonding dielectric layers 232 may be formed over the planar top surface of the SoIC package 200. The bonding dielectric layers 232 may be formed of silicon oxide, silicon oxynitride, silicon oxy-carbide, or the like. The conductive pads 236 may be formed within the topmost layer of the bonding dielectric layers 232 and exposed on a top surface 232t of the bonding dielectric layers 232. Conductive features 234 may be formed in the bonding dielectric layers 232. The conductive features 234 connect the conductive pads 236 to components in the device dies 202, such as the through semiconductor vias 210. The conductive pads 236 and conductive features 234 may be formed by damascene processes. A planarization process is performed so that the conductive pads 236 are exposed from the top surface 232t of the bonding dielectric layers 232. The conductive pads 236 are positioned for bonding with conductive pads formed on another device die. The conductive pads 236 may be formed from a metallic material, such as copper or copper alloy, or another metallic material that can diffuse in a subsequent anneal process so that metal-to-metal direct bond may be formed. After operation 114, a first die tier 238 is completed.

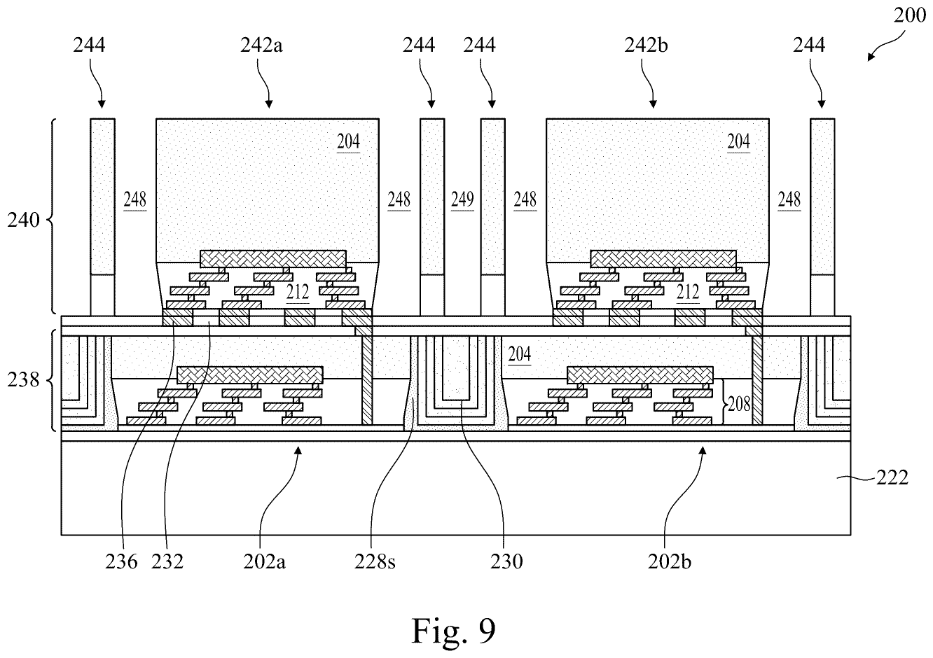

In operation 116, device dies 242 and, optionally, dummy dies 244, for a second die tier 240 are bonded to the first die tier 238, as shown in FIGS. 9 and 9A. FIG. 9A is a schematic partial top view of the second die tier 238. FIG. 9 is a schematic sectional view of the SoIC package 200 along the line 9-9 on FIG. 9A.

The device dies 242 for the second die tier 240 may be similar to the device dies 202 for the first die tier 238. Each device die 242 may include a device layer 206 formed on a semiconductor substrate 204, and an interconnect structure 208 formed on the device layer 206. Conductive pads 246 may be formed in dielectric layers 247 deposited on the interconnect structure 208 of the device dies 242. The conductive pads 246 may be in electrical connection with the interconnect structure 208 and configured to bond with the conductive pads 236 in the device dies 202 of the first die tier 238.

In some embodiments, bonding of the device dies 202 and 242 may be achieved through hybrid bonding. For example, the conductive pads 246 are bonded to the conductive pads 236 through metal-to-metal direct bonding. In some embodiments, the metal-to-metal direct bonding is copper-to-copper direct bonding. The conductive pads 246 may have sizes greater than, equal to, or smaller than, the sizes of the respective conductive pads 236. Furthermore, the topmost dielectric layer 232 on the first die tier 238 is bonded to the topmost dielectric layer 247 of the device dies 242 through dielectric-to-dielectric bonding, which may be fusion bonding, for example, with Si—O—Si bonds generated. To achieve the hybrid bonding, the device dies 242 are first pre-bonded by aligning with the corresponding device dies 202 and lightly pressing individual device dies 242 against in the first die tier 238. After all the device dies 242 are pre-bonded to the first die tier 238, an anneal process is performed to cause the inter-diffusion of the metals in the conductive pads 236 and the corresponding overlying conductive pads 246. After the anneal process, the conductive pads 246 are bonded to the corresponding conductive pads 236 through direct metal bonding caused by metal inter-diffusion.

In some embodiments, the second die tier 240 may include the dummy dies 244 to reduce gaps between the device dies 242. Each dummy die 244 may include a semiconductor portion and a dielectric portion. The dummy dies 244 may be bonded to the first die tier 238 by the dielectric portion using an adhesive layer or by a dielectric-to-dielectric bonding.

As shown in FIG. 9A, in some embodiments, the device dies 242 and the dummy dies 244 may be arranged with gaps 248, 249, 250, 251 formed therebetween. The gaps 250, 251 may be wider than the gaps 248, 249. The gaps 248 are formed between a device die 242 and a dummy die 244 and have a width W3. In some embodiments, the width W3 is in a range between about 60 μm and about 80 μm. The gaps 249 are formed between two dummy dies 244 and have a width W4. In some embodiments, the width W4 is in a range between about 75 μm and about 95 μm. The gaps 250 are formed between a device die 242 and a dummy die 244 and have a width W5. In some embodiments, the width W5 is in a range between about 530 μm and about 570 μm. The gaps 251 are formed between two dummy dies 244 and have a width W6. In some embodiments, the width W6 is in a range between about 190 μm and about 210 μm.

The device dies 242 may be the identical or different depending on particular design of the SoIC dies to be formed. Because the ILD layers 212 in the device dies 242 may have suffered a shrinkage, after the device dies 242 are bonded to the first die tier 238 with the ILD layers 212 facing down, the gaps 248, 250 are trenches with a wider bottom and narrower entrance. Similar to the gaps 224, 226, the gaps 248, 250 may have a wider upper portion and a narrower bottom portion.

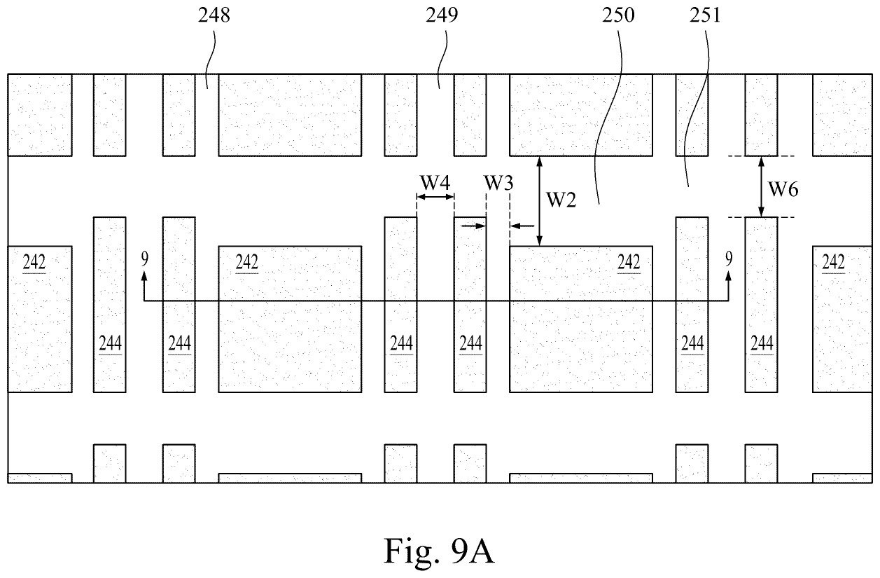

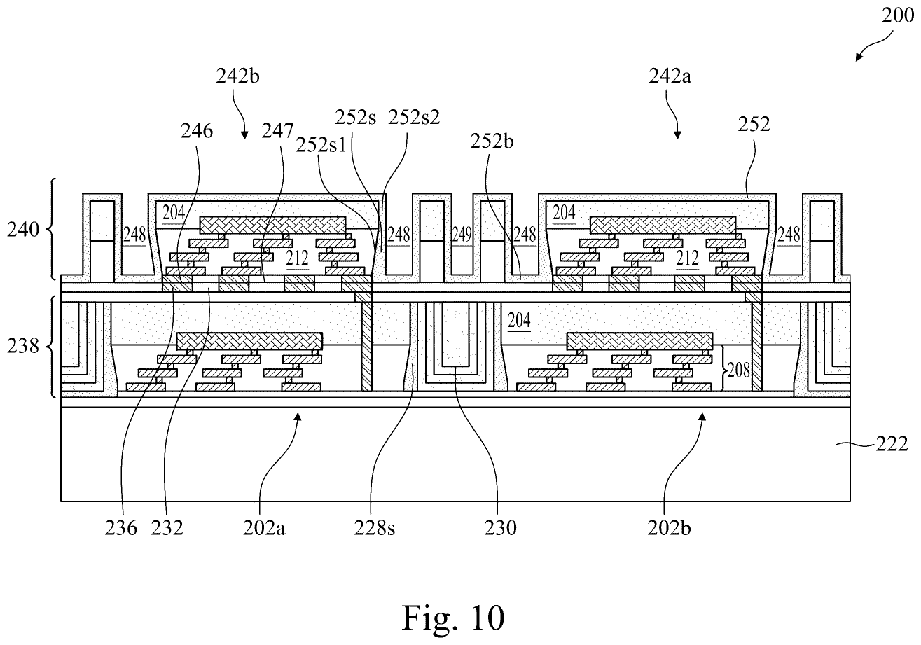

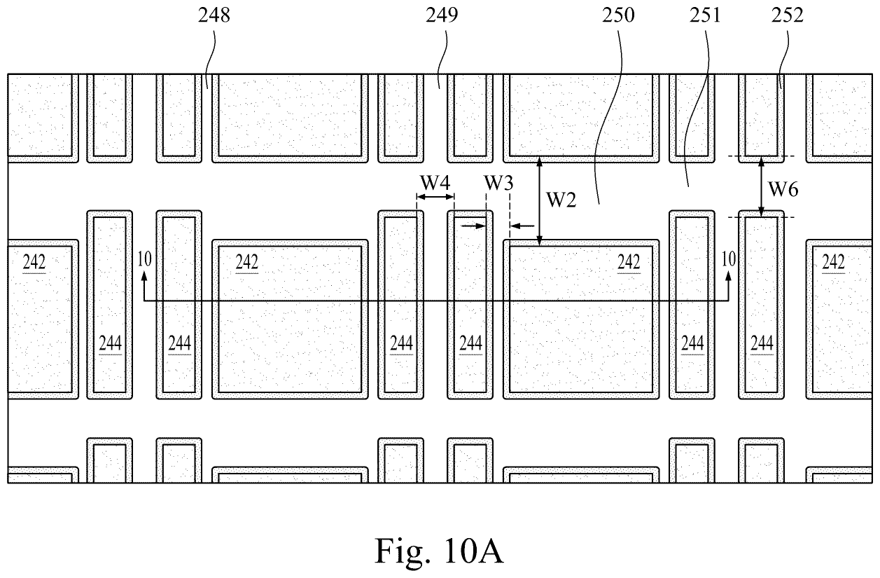

In operation 118, a glue layer 252 is deposited on exposed surfaces of the SoIC package 200, as shown in FIGS. 10 and 10A. FIG. 10A is a schematic partial top view of the SoIC package 200. FIG. 10 is a schematic sectional view of the SoIC package 200 along the line 10-10 on FIG. 10A.

In some embodiments, a back grinding, similar to the backside grinding described in operation 106, may be performed to reduce thickness of the substrate portions in the device dies 242 and the dummy dies 244 prior to deposition of the glue layer 252.

The glue layer 252 is similar to the glue layer 228 and may be formed by similar methods as described in operation 108. The glue layer 252 may include sidewall portions 252s in contact with sidewalls of the device dies 242 and bottom portions 252b in contact with the dielectric layer 232 on the first tie tier 238. For example, as shown in FIG. 10, in the gap 248, the sidewall portion 252s may have a thickness Ts and the bottom portion 228b may have a thickness Tb. In some embodiments, the thickness Ts may be in a range between about 500 angstroms and about 2000 angstroms. In some embodiments, the thickness Tb may be in a range between about 750 angstroms and about 2000 angstroms.

In some embodiments, the sidewall portions 252s of the glue layer 252 have a non-uniform sidewall thickness, thus, altering a bottom corner of the gap 248, 250. As shown in FIG. 10, the sidewall portion 252s has a first side 252s1 in contact with the device die 242 and a second side 252s2 exposed to the gap 248. As shown in FIG. 10, the upper portion of the sidewall portion 252s is thinner than the lower portion of the sidewall portion 252s.

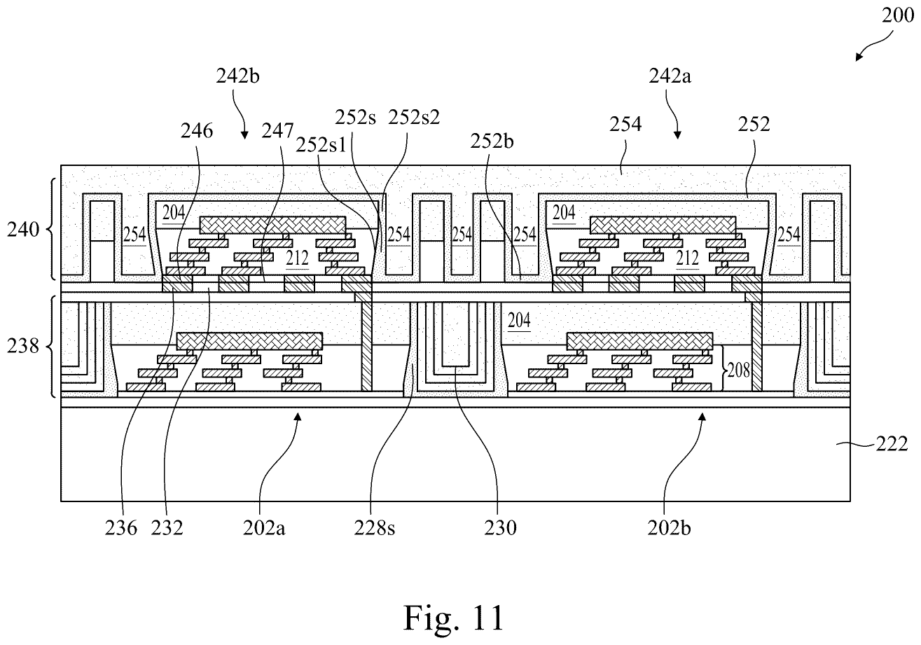

In operation 120, a dielectric filling material 254 is filled in the gaps 248, 249, 250, 251 over the glue layer 252, as shown in FIG. 11. Operation 120 is similar to the operation 110 described above. The dielectric filling material 254 and the dielectric filling material 230 are formed in the similar manner and with similar properties. As shown in FIG. 11, the gaps 248, 429, 250, 251 in the second die tier 240 are fully filled with the dielectric filling material 254.

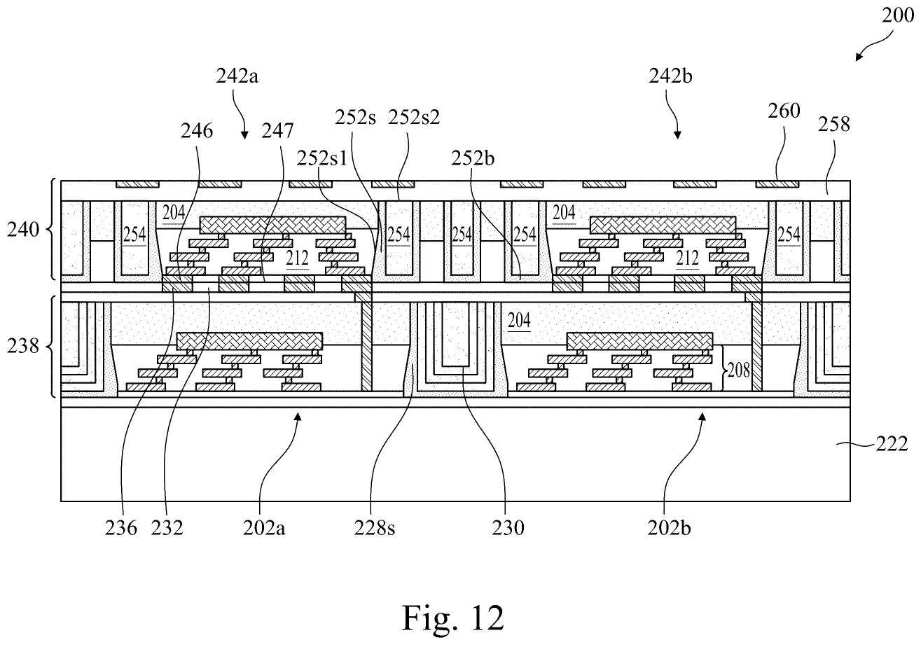

In operation 122, a planarization process is performed to remove the excessive dielectric filling material 254 and expose the device dies 242, as shown in FIG. 12. In some embodiments, the planarization process may be performed by a CMP process. In some embodiments, the planarization process may further grind down the semiconductor substrate 204. During planarization process, after the device dies 242 are exposed, the device dies 242 is subject to external shearing forces. The device dies 242 may be pulled off by the CMP pad or cracked (arcing) during planarization if not securely attached. The glue layer 252 according to the present disclosure improves adhesion between the device dies 242 and the dielectric filling material 254, thus, preventing loss of device dies 242 during the planarization process.

In some embodiments, dielectric layers 258 and conductive features 260 may be on the second die tier 240 after the planarization process. The conductive features 260 may be in electrical connection with components in the device dies 242 and/or with the device dies 202 via the conductive pads 246. The conductive features 260 may be used to bond with an interposer or redistribution lines (RDLs) in subsequent packaging.

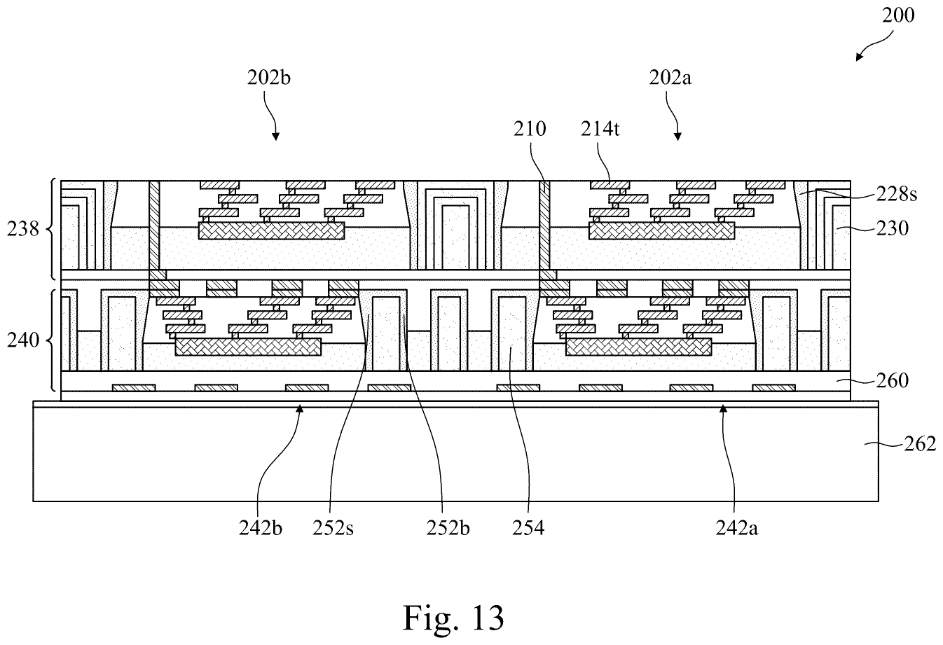

In operation 124, a second carrier wafer 262 is bonded to the SoIC package 200, as shown in FIG. 13. The second carrier wafer 262 is bonded to the second die tier 240. The first carrier wafer 222 is removed. The SoIC package 200 is then flipped over. In some embodiments, a planarization process may be performed to expose the top metal layer 214t and the through semiconductor vias 210 in the device dies 202 for subsequent processing. In some embodiments, the bottom portions 228b of the glue layer 228 are removed during the planarization process.

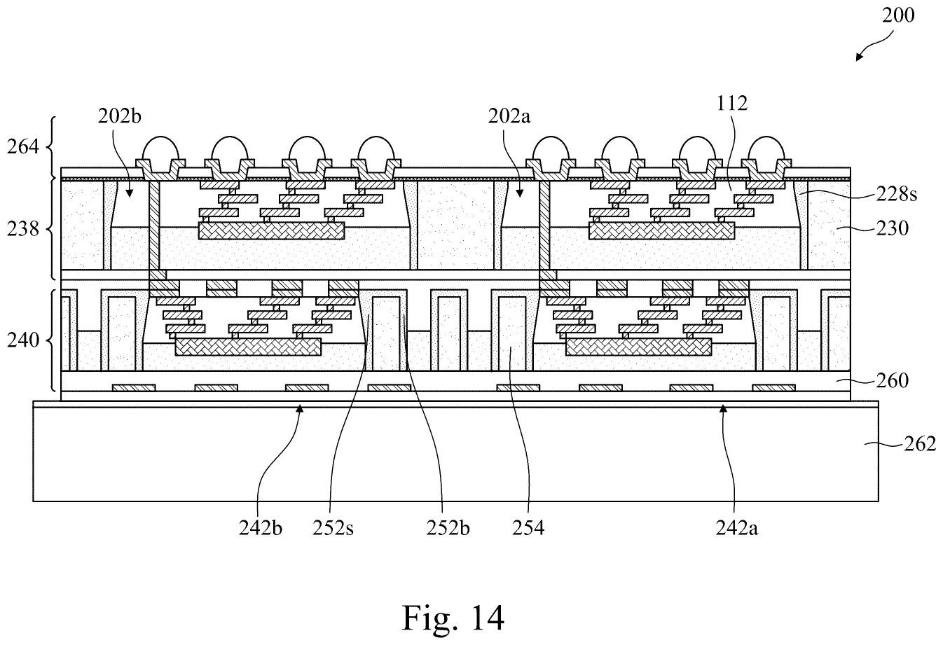

In operation 126, a RDL layer 264 is formed over the SoIC package 200, as shown in FIG. 14. The RDL layer 264 may include conductive features formed in dielectric layers and passivation layers. Depending on the subsequent application of the SoIC package 200, the RDL layer 264 may include various designs, for example contact pads, bonding pads, micro pads, under-bump metallizations (UBMs), and other suitable structures. After operation 126, the SoIC package 200 may be diced to individual SoIC dies and applied to various devices.

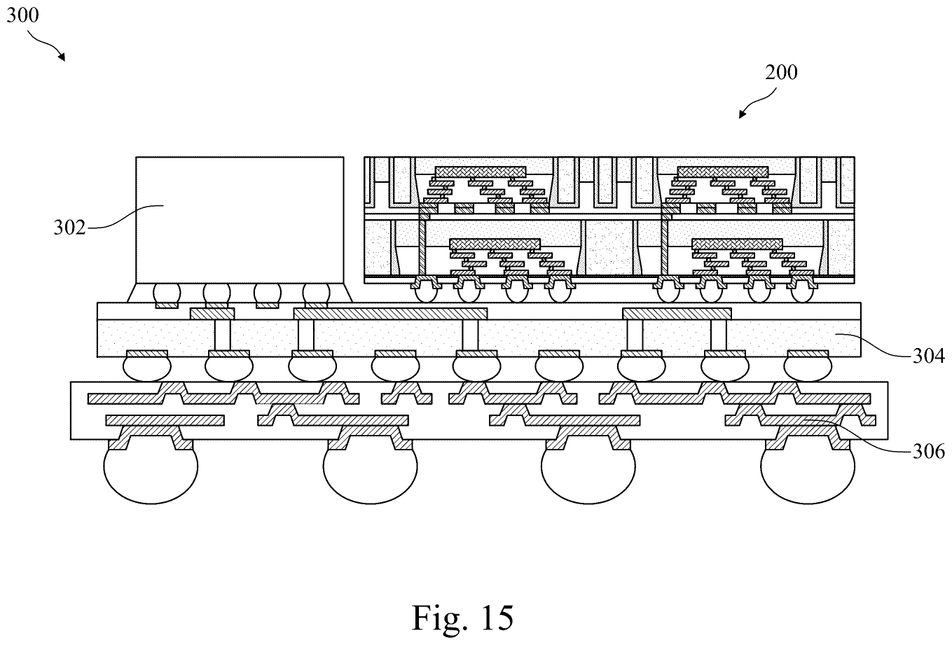

FIG. 15 is a schematic sectional view of a Chip-on-Wafer-on-Substrate (CoWoS) device 300 including the SoIC die 200 according to the present disclosure. The CoWoS device 300 may include the SoIC die 200, which may include logic dies and CPU dies, and a memory die 302. The SoIC die 200 and the memory die 302 disposed side by side on an interposer 304 and in electric communication with the interpose 304. The interposer 304 is disposed on and connected to a RDL substrate 306.

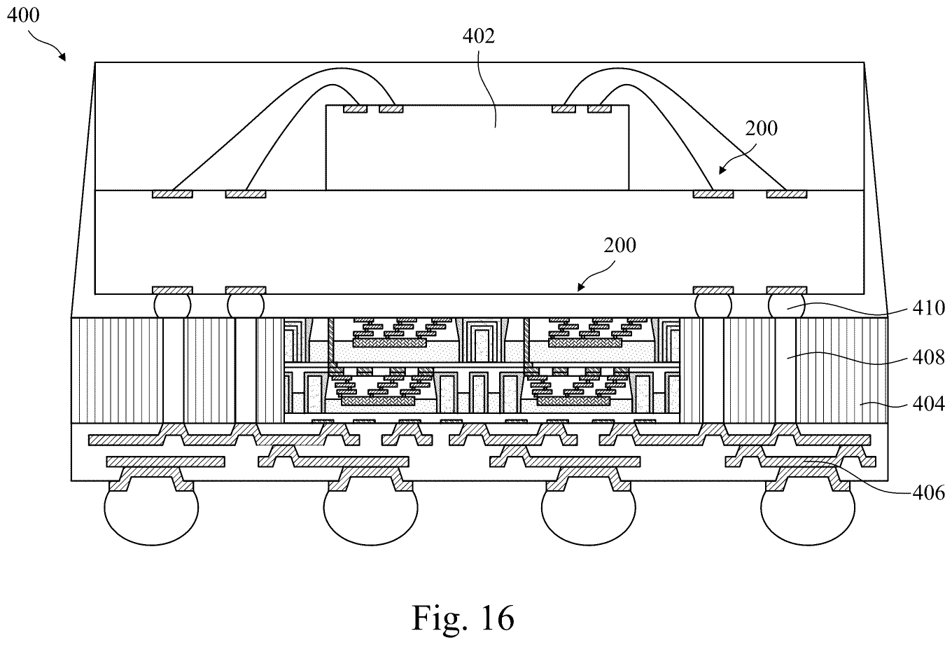

FIG. 16 is a schematic sectional view of an Integrated Fan Out Package-on-Package (InFO POP) device 400 including the SoIC die 200 according to the present disclosure. The InFO POP device 400 includes the SoIC die 200 disposed on and connected to a RDL substrate 406. An insulation layer A memory package 402 is disposed above the SoIC die 200. A plurality of through-vias 408 extending from the RDL substrate 406 besides the SoIC die 200. An encapsulating material 404 fills the gaps between neighboring through-vias 408 and the SoIC die 200 forming a package. A memory package 402 is disposed above the SoIC die 200 and the encapsulating material 404. Bond pads 410 connect the memory package 402 to the RDL substrate 406 through the through vias 408.

Embodiments of the present disclosure provide various advantages. By depositing a glue layer on sidewalls of semiconductor dies prior to depositing a dielectric filling material between semiconductor dies, embodiments of the present disclosure improve adhesion between the semiconductor dies and the dielectric filling material, thus reducing loss of semiconductor dies and reducing arcing during subsequent fabrication.

Some embodiments provide a method comprising attaching a first semiconductor die on a top surface of a carrier wafer, wherein a sidewall of the first semiconductor die is sloped, and a first angle is formed between the sidewall of the first semiconductor die and the top surface of the carrier wafer; depositing a glue layer, wherein a sidewall portion of the glue layer is formed on the sidewall of the first semiconductor die, a bottom portion of the glue layer is formed on the top surface of the carrier wafer, the sidewall portion and the bottom portion form a second angle, and the second angle is greater than the first angle; and depositing a dielectric filling material on the glue layer.

Some embodiments provide a method comprising: attaching a first device die and a second device die on a carrier wafer, wherein a first gap is formed between the first device die and the second device die; depositing a first glue layer on exposed surfaces of the first device die, the second device die, and the carrier wafer; depositing a first dielectric filling material on the first glue layer, wherein the first dielectric filling material fills the first gap between the first device die and second device die; forming a bonding dielectric layer over the first device die, the second device die, and the first dielectric filling material; bonding a third device die and a dummy die on a top surface of the bonding dielectric layer, wherein a second gap is formed between the third device die and the dummy die; depositing a second glue layer on sidewalls of the third device die and the dummy die and the top surface of the bonding dielectric layer; and depositing a second dielectric filling material on the second glue layer, wherein the second dielectric filling material fills the second gap between the third device die and the dummy die.

Some embodiments provide a semiconductor package, comprising: a first device die having a first sidewall and a dielectric top surface, wherein the first sidewall and the dielectric top surface form a first angle; a dielectric filling material disposed along the first sidewall; and a glue layer disposed between the first device die and the dielectric filling material, wherein a first side of the glue layer is in contact with the first sidewall of the first device die, a second side of the glue layer is in contact with the dielectric filling material, the second side of the glue layer and the dielectric top surface of the first device die form a second angle, and the first angle is greater than the second angle.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor package, comprising:
a first device die having a first sidewall and a dielectric top surface, wherein the first sidewall and the dielectric top surface form a first angle;
a dielectric filling material disposed along the first sidewall; and
a glue layer disposed between the first device die and the dielectric filling material, wherein a first side of the glue layer is in contact with the first sidewall of the first device die, a second side of the glue layer is in contact with the dielectric filling material, the second side of the glue layer and the dielectric top surface of the first device die form a second angle, and the first angle is greater than the second angle.

2. The semiconductor package of claim 1, wherein:
the glue layer comprises silicon nitride or silicon carbide nitride; and
the dielectric filling material comprises a low-k dielectric material formed from one of TEOS and mDEOS.

3. The semiconductor package of claim 2, wherein the glue layer has a thickness in a range between about 750 angstroms and about 2000 angstroms.

4. The semiconductor package of claim 1, further comprising:
a second die disposed side by side with the first device die, wherein the second die has a second sidewall facing the first sidewall of the first device die, and the dielectric filling material is disposed between the first sidewall and second sidewall.

5. The semiconductor package of claim 4, wherein the second die is a device die.

6. The semiconductor package of claim 4, wherein the second die is a dummy die.

7. The semiconductor package of claim 1, wherein the glue layer has a greater thickness on the first sidewall of the first device die near the dielectric top surface than other portions on the first sidewall.

8. The semiconductor package of claim 1, wherein the glue layer is performed at a temperature range between a temperature between about 270° C. and 280° C.

9. A semiconductor package, comprising:
a first die comprising:
a substrate;
a device layer formed on the substrate; and
an interconnect structure formed over the device layer, wherein the interconnect structure has sloped sidewalls;
a second die disposed side by side with the first die;
a glue layer around the first die and the second die, wherein the glue layer has increased thickness on the sloped sidewalls of the interconnect structure of the first die; and
a dielectric filling material disposed on the glue layer between the first die and the second die.

10. The semiconductor package of claim 9, wherein the glue layer comprises the glue layer comprises silicon nitride or silicon carbide nitride.

11. The semiconductor package of claim 10, wherein the glue layer has a thickness in a range between about 750 angstroms and about 2000 angstroms.

12. The semiconductor package of claim 9, wherein the dielectric filling material comprises a low-k dielectric material formed from one of TEOS and mDEOS.

13. The semiconductor package of claim 9, wherein the second die is a dummy die.

14. A semiconductor package, comprising:
a first device die;
a second device die disposed side by side with the first device die, wherein a bottom surface of the first device aligns with a bottom surface of the second device die;
a first glue layer disposed on a first sidewall of the first device die and a second sidewall of the second device die, wherein the first sidewall of the first device die slopes towards the bottom surface of the first device die, and a thickness of the first glue layer increases towards the bottom surface of the first device die;
a first dielectric filling material disposed on the first glue layer, wherein the first dielectric filling material fills a gap between the first device die and second device die;
a bonding dielectric layer disposed over the first device die, the second device die, and the first dielectric filling material; and
a third device die disposed over the bonding dielectric layer.

15. The semiconductor package of claim 14, further comprising:
a second glue layer disposed on sidewalls of the third device and the bonding dielectric layer, wherein a thickness of the second glue layer increases towards the bonding dielectric layer.

16. The semiconductor package of claim 15, further comprising:
a dummy die disposed on the bonding dielectric layer, wherein the second glue layer is disposed on sidewalls of the dummy die; and
a second dielectric filling material disposed the second glue layer, wherein the second dielectric filling material fills a gap between the third device die and the dummy die.

17. The semiconductor package of claim 14, further comprising:
a conductive pad disposed in the bonding dielectric layer, wherein the conductive pad is electrically coupled to the third device die.

18. The semiconductor package of claim 17, wherein the conductive pad is electrically coupled to a through substrate via in the first device die.

19. The semiconductor package of claim 14, further comprising:
a RDL layer disposed on the bottom surface of the first device die and the first device die.

20. The semiconductor package of claim 14, further comprising:
a RDL substrate, wherein the first device die and the second device die are disposed on the RDL substrate.
